(19) United States
(12) Patent Application Publication
(10) Pub. No.: US 2026/0370127 A1
(43) Pub. Date: Nov. 19, 2026

(54) METHODS AND APPARATUS FOR CONTROLLING SWITCHING IN POWER CONVERTERS

(71) Applicant: ENPHASE ENERGY, INC., Fremont, CA (US)

(72) Inventor: Michael J. HARRISON, Petaluma, CA (US)

(21) Appl. No.: 19/515,862

(22) PCT Filed: Aug. 15, 2024
(86) PCT No.: PCT/US2024/042444

§ 371 Date: Mar. 3, 2026

Related U.S. Application Data
(60) Provisional application No. 63/536,595, filed on Sep. 5, 2023.

(51) Int. Cl. H02M 1/088; H02M 1/36; H02M 7/5375; H02M 7/5387; H03K 17/687

(52) U.S. Cl. CPC H02M 1/088; H02M 1/36; H02M 7/5375; H02M 7/53873; H03K 17/6874

(57) ABSTRACT

A switch of a bridge configured for use with a power converter is provided herein. The switch comprises multiple Gate drivers coupled to corresponding Gates and configured to coordinate a start-up of the multiple Gate drivers for driving output Gate signals to the corresponding Gates when a common start-up signal having a first frequency and a second signal having a second frequency different from the first frequency is provided to the multiple Gate drivers.

### BACKGROUND

### Field of the Disclosure

Embodiments of the present disclosure relate generally to power conversion systems and, in particular, to methods and apparatus for coordinating a start-up of multiple Gate drivers.

### Description of the Related Art

Conventional power converters suitable for use with power conversion systems are known. The power converters can comprise one or more bridges that comprise one or more switches that are driven by an isolated gate driver connected to one or more transistors (e.g., GaN HEMT (High Electron Mobility Transistor) devices, Si Super-Junction (SJ) MOSFET devices, etc.).

Some isolated Gate drivers require two isolated components to separately isolate the Gate drive signal and Gate drive power, while others use an isolation transformer to isolate the Gate drive signal and the Gate drive power. With respect to the latter, a drive signal needs to be applied to the isolation transformer to provide isolated power for the Gate driver. The power-up process for the isolated Gate driver, however, requires an indeterminant amount of time. For example, if multiple Gate drivers are used in a power converter (which is usually the case), the multiple Gate drivers complete the power-up sequence (e.g., exit UVLO (under voltage lockout)) at slightly different points in time. If each Gate driver starts operating (e.g., driving the output Gate signal) as soon as the Gate driver completes the power up sequence, a sporadic uncoordinated start-up of the power converter can occur, which can damage the hardware of the power converter.

Thus, there is a need for improved methods and apparatus for coordinating a start-up of multiple Gate drivers.

### SUMMARY

In accordance with at least some embodiments, there is provided a switch of a bridge configured for use with a power converter. The switch comprises multiple Gate drivers coupled to corresponding Gates and configured to coordinate a start-up of the multiple Gate drivers for driving output Gate signals to the corresponding Gates when a common start-up signal having a first frequency and a second signal having a second frequency different from the first frequency is provided to the multiple Gate drivers.

In accordance with at least some embodiments, there is provided a power conversion system. The power conversion system comprises a converter, a DC component coupled to a DC side of the converter, a plurality of switches coupled to a primary winding of a transformer, and a bridge coupled to a secondary winding of the transformer and comprising a switch, the switch comprising multiple Gate drivers coupled to corresponding Gates and configured to coordinate a start-up of the multiple Gate drivers for driving output Gate signals to the corresponding Gates when a common start-up signal having a first frequency and a second signal having a second frequency different from the first frequency is provided to the multiple Gate drivers.

In accordance with at least some embodiments, there is provided a method for coordinating a start-up of multiple Gate drivers. The method comprises determining when a common start-up signal having a first frequency and a second signal having a second frequency different from the first frequency is provided to multiple Gate drivers configured to coordinate a start-up of the multiple Gate drivers for driving output Gate signals to corresponding Gates.

Various advantages, aspects, and novel features of the present disclosure may be appreciated from a review of the following detailed description of the present disclosure, along with the accompanying figures in which like reference numerals refer to like parts throughout.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic diagram of a power conversion system comprising a switched mode power converter in accordance with embodiments of the present disclosure;

FIG. 2 is a schematic diagram of a power conversion system comprising a switched mode power converter in accordance with embodiments of the present disclosure;

FIG. 3 is a schematic diagram of gate drivers and corresponding GaN HEMT devices in accordance with embodiments of the present disclosure;

FIG. 4 is a diagram of a gate driver in accordance with embodiments of the present disclosure;

FIG. 5 is a diagram of input signals on a frequency spectrum in accordance with embodiments of the present disclosure;

FIG. 6 is a diagram of various signals associated with a start-up sequence in accordance with embodiments of the present disclosure;

FIG. 7 is a diagram of various signals associated with a shut-down sequence in accordance with embodiments of the present disclosure; and

FIG. 8 is a flowchart of a method for coordinating a start-up of multiple isolated Gate drivers in accordance with embodiments of the present disclosure.

### DETAILED DESCRIPTION

Embodiments of the present disclosure are directed to improved methods and apparatus for coordinating a start-up of multiple Gate drivers. For example, a switch of a bridge configured for use with a power converter can comprise multiple Gate drivers that are coupled to corresponding Gates and configured to coordinate a start-up of the multiple Gate drivers for driving output Gate signals to the corresponding Gates when a common start-up signal having a first frequency and a second signal having a second frequency different from the first frequency is provided to the multiple Gate drivers.

The foregoing description of embodiments of the disclosure comprises a number of elements, devices, circuits and/or assemblies that perform various functions as described. These elements, devices, circuits, and/or assemblies are exemplary implementations of means for performing their respectively described functions.

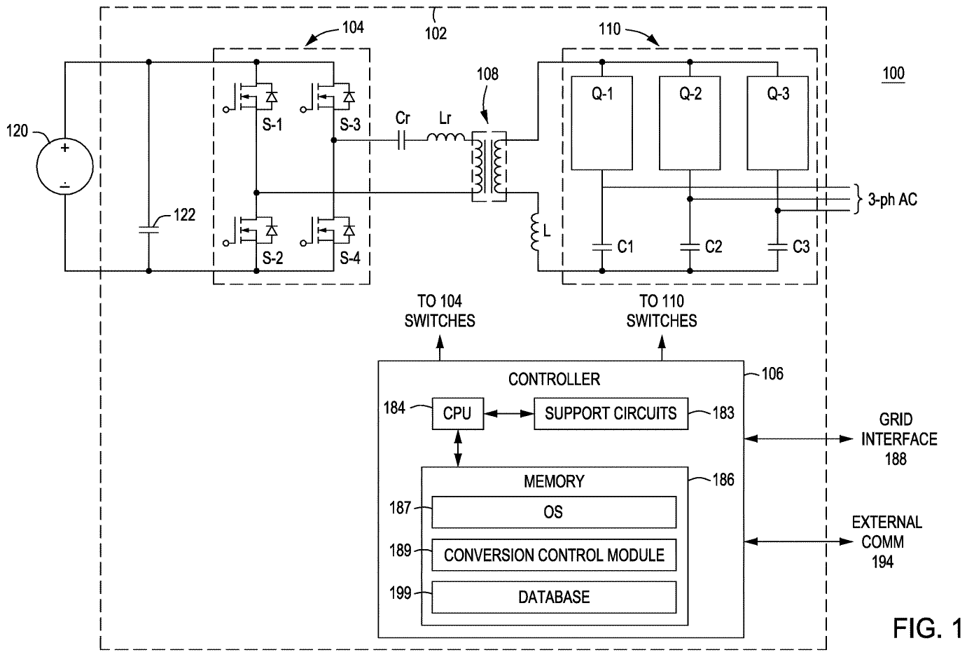

FIG. 1 is a schematic diagram of a power conversion system 100 comprising a converter 102 (e.g., a switched mode power converter) in accordance with embodiments of the present disclosure. This diagram only portrays one variation of the myriad of possible system configurations. The present disclosure can function in a variety of power generation environments and systems.

The power conversion system 100 comprises a DC component 120, such as a PV module or a battery, coupled to a DC side of the converter 102 (referred to herein as “converter 102”). In other embodiments the DC component 120 may be any suitable type of DC components, such as another type of renewable energy source (e.g., wind farms, hydroelectric systems, and the like), other types of energy storage components, and the like.

The converter 102 comprises a capacitor 122 coupled across the DC component 120 as well as across an H-bridge 104 formed from switches S-1, S-2, S-3 and S-4. The switches S-1 and S-2 are coupled in series to form a left leg of the H-bridge 104, and the switches S-3 and S-4 are coupled in series to form a right leg of the H-bridge 104.

The output of the H-bridge 104 is coupled across a series combination of a capacitor Cr and inductor L, which form a resonant tank, and the primary winding of a transformer 108. In other embodiments, the resonant tank may be formed by a different configuration of the capacitor Cr and the inductor Lr (e.g., the capacitor Cr and the inductor L may be coupled in parallel); in some embodiments, Lr may represent a leakage inductance from the transformer 108 rather than a physical inductor.

A series combination of the secondary winding of the transformer 108 and an inductor L is coupled across a bridge which produces a three-phase AC output, although in other embodiments the bridge may produce one or two phases of AC at its output. The bridge can be a half-bridge, full-bridge, Hex-bridge, etc. formed using switches that are arranged to enable current flow to be alternated. For example, the switches can comprise one or more semiconductor (or vacuum tube) devices, e.g., Field Effect Transistor (FET), Junction FET (JFET), Metal Oxide Semiconductor FET (MOSFET), High Electron Mobility Transistor (HEMT), etc. The switches can be used for AC-DC conversion and/or DC-AC conversion (e.g., switches that are controllable). The bridge can be a Bi-directional bridge (sometimes referred to as a cycloconverter bridge or cycloconverter for short) that uses two unidirectional switches connected in series (back-to-back, which can be referred to as Bi-directional switches)—which can conduct current in either direction (when turned on), can block a voltage of either polarity (when turned off), and can also block a voltage in both polarities (e.g., block polar voltage). For illustrative purposes, the secondary winding of the transformer 108 and the inductor L are assumed coupled across a cycloconverter 110. The cycloconverter 110 comprises three 4Q bi-directional switches Q-1, Q-2, and Q-3 (which may be collectively referred to as switches Q) respectively in a first leg, a second leg, and a third leg coupled in parallel to one another. In accordance with embodiments of the present disclosure, each of the switches Q-1, Q-2, and Q-3 is a native four quadrant bi-directional switch comprising one or more of the aforementioned semiconductor (or vacuum tube) devices. Alternatively or additionally, the cycloconverter 110 can comprise three monolithically formed switches (e.g., a Monolithic Bi-Directional Switch (MBDS))—Gallium-Nitride (GaN) based on a HEMT structure, as described in greater detail below. That is, the MBDS refers to the fact that this Bi-Directional Switch (BDS) can be built in a single semiconductor die. In at least some embodiments, each of the switches Q-1, Q-2, and Q-3 comprises a pair of Gallium-Nitride (GaN) High Electron Mobility Transistors. In at least some embodiments, each of the switches Q-1, Q-2, and Q-3 comprises a first pair of Gallium-Nitride (GaN) High Electron Mobility Transistors and a second pair of Gallium-Nitride (GaN) High Electron Mobility Transistors connected in series.

The first cycloconverter leg comprises the 4Q switch Q-1 coupled to a capacitor C1, the second cycloconverter leg comprises the 4Q switch Q-2 coupled to a capacitor C2, and the third cycloconverter leg comprises a 4Q switch Q-3 coupled to a capacitor C3. A first AC output phase line is coupled between the switch Q-1 and the capacitor C1, a second AC output phase line is coupled between the switch Q-2 and the capacitor C2, and a third AC output phase line is coupled between the switch Q-3 and the capacitor C3. The converter 102 may also include additional circuitry not shown, such as voltage and/or current monitors, for obtaining data for power conversion, data reporting, and the like.

The converter 102 additionally comprises a controller 106 coupled to the H-bridge switches (S-1, S-2, S-3, and S-4) and the cycloconverter switches (Q-1, Q-2, and Q-3) for operatively controlling the switches to generate the desired output power. In some embodiments, the converter 102 may function as a bi-directional converter.

The controller 106 comprises a CPU 184 coupled to each of support circuits 183 and a memory 186. The CPU 184 may comprise one or more conventionally available microprocessors or microcontrollers. Additionally or alternatively, the CPU 184 may include one or more application specific integrated circuits (ASICs). The support circuits 183 are well known circuits used to promote functionality of the CPU 184. Such circuits include, but are not limited to, a cache, power supplies, clock circuits, buses, input/output (I/O) circuits, and the like. The controller 106 may be implemented using a general purpose computer that, when executing particular software, becomes a specific purpose computer for performing various embodiments of the present disclosure.

The memory 186 is a non-transitory computer readable storage medium such as random access memory, read only memory, removable disk memory, flash memory, and various combinations of these types of memory. The memory 186 is sometimes referred to as main memory and may, in part, be used as cache memory or buffer memory. The memory 186 generally stores the OS 187 (operating system), if necessary, of the controller 106 that can be supported by the CPU capabilities. In some embodiments, the OS 187 may be one of a number of commercially available operating systems such as, but not limited to, LINUX, Real-Time Operating System (RTOS), and the like.

The memory 186 may store various forms application software (e.g., instructions), such as a conversion control module 189 for controlling power conversion by the converter 102, for example maximum power point tracking (MPPT), switching, performing the methods described herein, and the like. The memory 186 may further store a database 199 for storing various data. The controller 106 further processes inputs and outputs to external communications 194 (i.e., gateway) and a grid interface 188.

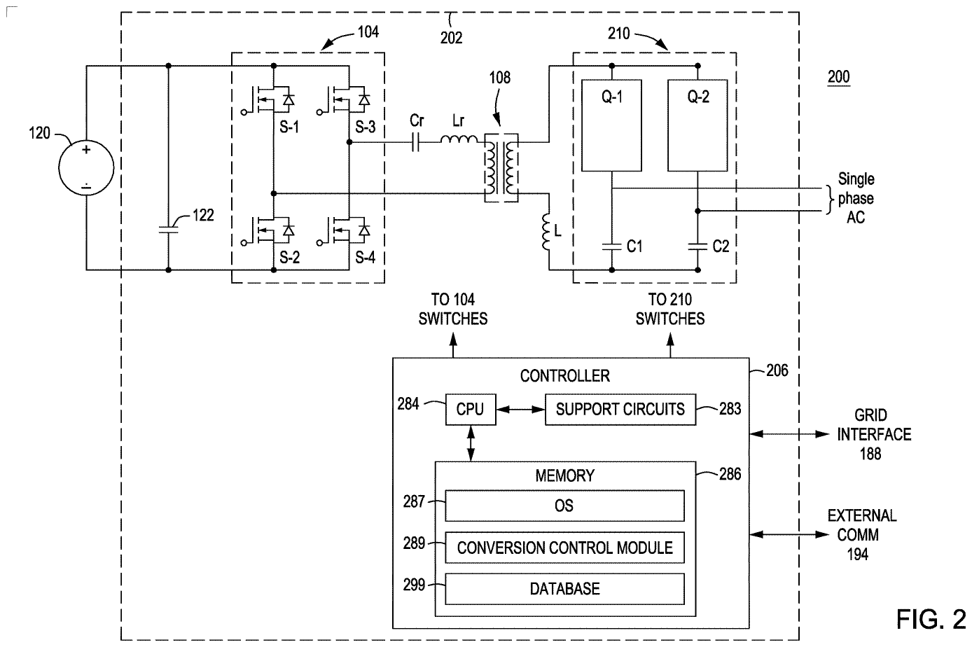

FIG. 2 is a schematic diagram of a power conversion system 200 comprising a converter 202 (e.g., a switched mode power converter) in accordance with embodiments of the present disclosure.

The power conversion system 200 comprises the DC component 120 coupled to a DC side of the converter 202. The converter 202 comprises the capacitor 122 coupled across the DC component 120 and the H-bridge 104, as described above with respect to the converter 102. The output of the H-bridge 104 is coupled across a series combination of the capacitor Cr and the inductor Lr, which form a resonant tank, and the primary winding of the transformer 108, as described above with respect to the converter 102. In other embodiments, the resonant tank may be formed by a different configuration of the capacitor Cr and the inductor Lr (e.g., the capacitor Cr and the inductor L may be coupled in parallel); in some embodiments, Lr may represent a leakage inductance of the transformer 108 rather than a physical inductor.

A series combination of the secondary winding of the transformer 108 and the inductor L can be coupled across a bridge as described above with respect to FIG. 1. For example, the secondary winding of the transformer 108 and the inductor L can be coupled across a cycloconverter 210 which produces a single-phase AC output. For example, the cycloconverter 210 comprises two bi-directional switches Q-1 and Q-2, (collectively referred to as switches Q) respectively in a first leg and a second leg coupled in parallel to one another. In accordance with embodiments of the present disclosure, each of the switches Q-1 and Q-2 is a native four quadrant bi-directional switch comprising one or more of the aforementioned semiconductor (or vacuum tube) devices. Alternatively or additionally, the cycloconverter 210 can comprise two monolithically formed switches (e.g., a Monolithic Bi-Directional Switch (MBDS))—Gallium-Nitride (GaN) based on a HEMT structure, as described in greater detail below. In at least some embodiments, each of the switches Q-1 and Q-2 comprises a pair of Gallium-Nitride (GaN) High Electron Mobility Transistors. In at least some embodiments, each of the switches Q-1 and Q-2 comprises a first pair of Gallium-Nitride (GaN) High Electron Mobility Transistors and a second pair of Gallium-Nitride (GaN) High Electron Mobility Transistors connected in series.

The first cycloconverter leg comprises the 4Q switch Q-1 coupled to the capacitor C1, and the second cycloconverter leg comprises the 4Q switch Q-2 coupled to the capacitor C2. A first AC output phase line is coupled between the switch Q-1 and the capacitor C1, and a second AC output phase line is coupled between the switch Q-2 and the capacitor C2. The converter 202 may also include additional circuitry not shown, such as voltage and/or current monitors, for obtaining data for power conversion, data reporting, and the like.

The converter 202 additionally comprises a controller 206 coupled to the H-bridge switches (S-1, S-2, S-3, and S-4), and the cycloconverter switches (Q-1 and Q-2) for operatively controlling the switches to generate the desired output power. In some embodiments, the converter 202 may function as a bi-directional converter.

The controller 206 comprises a CPU 284 coupled to each of support circuits 283 and a memory 286. The CPU 284 may comprise one or more conventionally available microprocessors or microcontrollers. Additionally or alternatively, the CPU 284 may include one or more application specific integrated circuits (ASICs). The support circuits 283 are well known circuits used to promote functionality of the CPU 284. Such circuits include, but are not limited to, a cache, power supplies, clock circuits, buses, input/output (I/O) circuits, and the like. The controller 206 may be implemented using a general purpose computer that, when executing particular software, becomes a specific purpose computer for performing various embodiments of the present disclosure.

The memory 286 is a non-transitory computer readable medium such as random access memory, read only memory, removable disk memory, flash memory, and various combinations of these types of memory. The memory 286 is sometimes referred to as main memory and may, in part, be used as cache memory or buffer memory. The memory 286 generally stores the OS 287 (operating system), if necessary, of the controller 206 that can be supported by the CPU capabilities. In some embodiments, the OS 287 may be one of a number of commercially available operating systems such as, but not limited to, LINUX, Real-Time Operating System (RTOS), and the like.

The memory 286 may store various forms of application software, such as a conversion control module 289 for controlling power conversion by the converter 202, for example maximum power point tracking (MPPT), switching, and the like. The memory 286 may further store a database 299 for storing various data. The controller 206 further processes inputs and outputs to external communications 194 (i.e., gateway) and the grid interface 188.

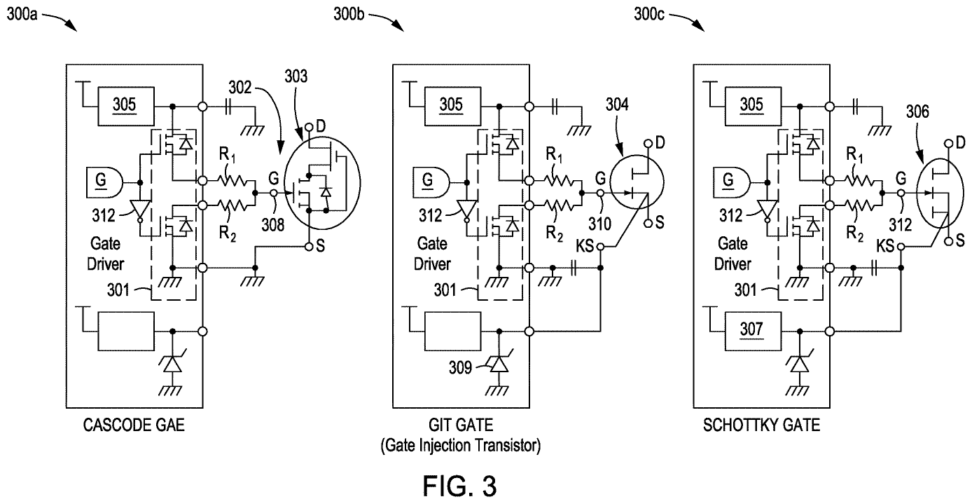

FIG. 3 is a schematic diagram of gate drivers (e.g., isolated gate drivers) and corresponding GaN HEMT devices in accordance with embodiments of the present disclosure. The one or more gate drivers are configured for use with one or more GaN HEMT devices (e.g., one or more of the bi-directional switches Q-1, Q-2, or Q-3). Accordingly, the one or more gate drivers are configured to provide an asymmetrical turn-on and turn-off capabilities. For example, the one or more gate drivers are configured to provide independent turn-on and turn-off output. For example, a turn-on output pin can pull up to the Gate G drive supply voltage when the Gate G driver is turned on, and, conversely, a turn-off output pin can pull down to the Gate G driver ground when the Gate G driver is turned off. Separate Gate G turn-on and turn-off resistors R1 and R2, respectively, can be used to connect the Gate G driver outputs to the transistor Gate 308, thus, providing an asymmetrical drive while eliminating the use of an external diode and the external diode's associated forward voltage drop.

Continuing with reference to FIG. 3, a gate driver 300a can be connected a Cascode GaN HEMT device 302, which is a fusion of a normally on (depletion mode) GaN HEMT connected to a low voltage normally off silicon (Si) MOSFET 303 to provide a required normally off system behavior. Accordingly, driving the Cascode GaN HEMT device 302 closely resembles a drive for a conventional Si MOSFET on the basis that the Cascode GaN HEMT device 302 is actually a Si MOSFET Gate. For example, the transistor Gate 308 input resembles a capacitor and the transistor Gate 308 threshold voltage is, typically, around 4V with the transistor Gate 308 drive voltage of about 9V to about 12V with a maximum the transistor Gate 308 drive voltage of about 16V to about 18V. The Cascode GaN HEMT device 302 does not require a negative transistor Gate turn-off voltage, as a 0V turn-on is adequate to ensure the Cascode GaN HEMT device 302 is turned fully off. Further, the use of a negative transistor Gate turn-off voltage unnecessarily increases the required transistor Gate 308 charge, which is already much higher (approximately 4×) for the Cascode GaN HEMT device 302 compared to a gate injection transistor (GIT) GaN eHEMT and a Schottky Gate GaN eHEMT.

For example, a gate driver 300b is configured for use with a GIT GaN eHEMT device 304, which features a junction Gate 310 that requires a drive voltage of approximately 1.2V and a sustained typical junction Gate 310 current of about 1 mA to about 10 mA. The junction Gate 310 is driven from the universal gate driver 300 via a resistor (e.g., resistor R1) to limit (set) the required junction Gate 310 drive current—accordingly the GIT GaN eHEMT device 304 junction Gate 310 drive solution does not require a well-regulated junction Gate 310 drive voltage (e.g., similar to the Si MOSFET). Since the junction Gate 310 threshold voltage is so low (e.g., typically, 1.2V, and getting as low as 0.7V at 125 °C), a negative junction Gate 310 turn-off voltage (e.g., via resistor R2) is required to ensure that the GIT GaN eHEMT device 304 can be reliably turned off. Due to the junction Gate 310 impact, the negative junction Gate 310 turn-off supply needs to be configured to sink current (e.g., via a Zener diode 309 or another device suitable for sinking current).

Likewise, a gate driver 300c is configured for use with a Schottky Gate GaN eHEMT device 306, which features a field effect Gate 312 structure that appears to be a capacitor with a field effect Gate 312 threshold of about 1V to about 2V, but requires an applied voltage of about 5V to fully turn the device on, and an absolute maximum field effect Gate 310 voltage of about 7V. The field effect Gate 312 drive solution for driving the Schottky Gate GaN eHEMT device 306 is well-regulated to achieve a recommended field effect Gate 312 drive voltage without endangering the Schottky Gate GaN eHEMT device 306 due to the field effect Gate 312 drive over-voltage. As with the GIT GaN eHEMT device 304, since the field effect Gate 312 threshold voltage for the Schottky Gate GaN eHEMT device 306 is so low (e.g., typically, 1.2V, and getting as low as 0.7V at 125 °C), a negative field effect Gate 310 turn-off voltage (e.g., via resistor R2) is required to ensure that the Schottky Gate GaN eHEMT device 306 can be reliably turned off. Unlike the GIT GaN eHEMT device 304, however, due to the capacitive field effect Gate 310 impact, the negative field effect Gate 310 turn-off supply needs to be configured to source current, e.g., via a 1.5 voltage regulator 307 or another device suitable for sourcing current).

In at least some embodiments, the gate drivers have independent turn-on and turn-off outputs (via the Resistors R1 and R2) for implementing asymmetrical Gate drive characteristics, has voltage regulated supply 305 (e.g., adjustable/programmable) to determine a Gate turn-on voltage, and an optional negative Gate turn-off voltage supply that can both sink (e.g., via the Zener diode 309) and source current (e.g., via the voltage regulator 307). Moreover, the gate drivers are also suitable for driving conventional Si MOSFETs (or IGBTs) on the basis that the Cascode GaN HEMT device 302 utilizes a Si MOSFET to drive the Cascode GaN HEMT device 302.

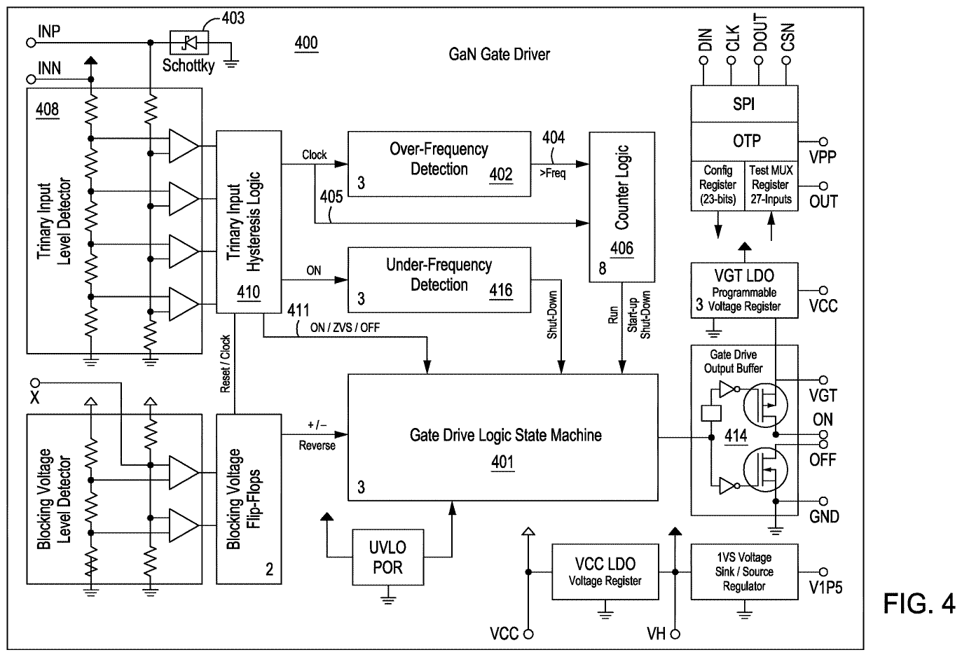

FIG. 4 is a diagram of a gate driver 400 (e.g., the gate driver 300a, the gate driver 300b, and/or the gate driver 300c) in accordance with embodiments of the present disclosure. For example, an over-frequency detector 402 can be used to differentiate between a normal switching Gate signal and a start-up signal (or in some cases a shut-down signal). The start-up signal has a frequency that is above a normal maximum switching (e.g., a >frequency 404 signal). For example, when the over-frequency detector 402 detects the start-up signal, the over-frequency detector 402 transmits the start-up signal to a counter logic circuit 406. When the counter logic circuit 406 receives the start-up signal, the counter logic circuit 406 transmits a run (e.g., the start-up signal or the shut-down signal) to a gate drive logic circuit 401, as described in greater detail below. In at least some embodiments, the counter logic circuit 406 is also configured to further differentiate the start-up signal signals based on how many cycles the start-up signal signals last. In such embodiments, the counter logic circuit 406 also receives a clock signal 405. For example, a trinary input signal can be treated as the clock signal 405. In at least some embodiments, there are two distinctly different mathematical operations performed to the clock signal 405. For example, 1) the over-frequency detector 402 (e.g., over-frequency detection logic) constantly monitors the clock signal 405 and compares the frequency of the clock signal 405 to an over frequency value and sets an output high or low depending on whether the clock frequency is above or below the over frequency value. 2) The counter logic circuit 406 (e.g., counter logic) counts the number of over frequency clock cycles. If the clock signal 405 is not over frequency then the counter logic circuit 406 is forced to its reset state (count=0). In this way the counter logic circuit 406 only counts up when the clock frequency is above the over frequency value.

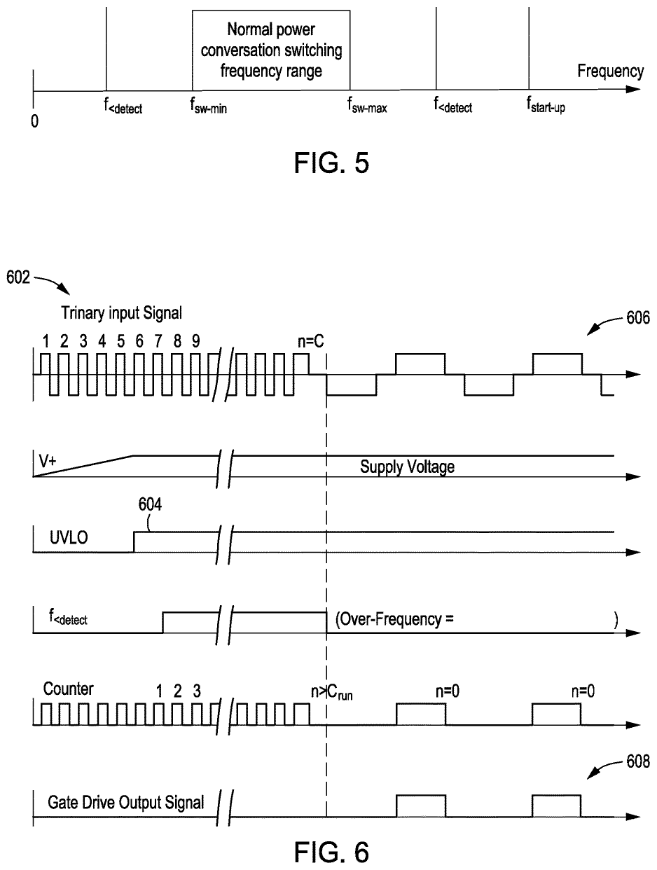

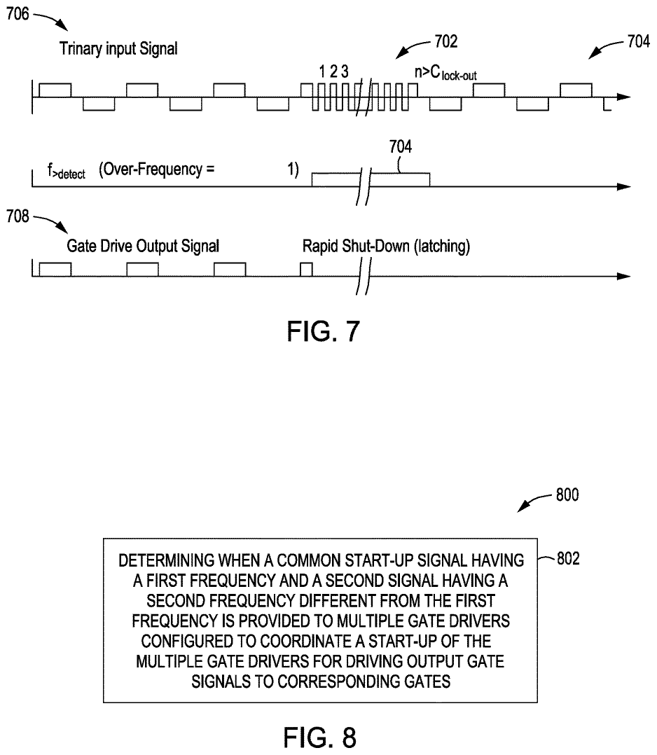

FIG. 5 is a diagram of input signals on a frequency spectrum, FIG. 6 is a diagram of various signals associated with a start-up sequence, FIG. 7 is a diagram of various signals associated with a shut-down sequence, and FIG. 8 is a flowchart of a method for coordinating a start-up of multiple Gate driver in accordance with embodiments of the present disclosure.

For example, FIG. 5 shows a normal switching frequency range, and above the normal switching frequency range (e.g., f_{sw-min} to f_{sw-max}) is a defined boundary over which a signal with a higher frequency is assumed to be a start-up frequency (e.g., fₛₜₐᵣₜ₋ᵤₚ). As illustrated in FIG. 5, the inventor has found that achieving a clear distinction between a signal that is considered to be part of the normal switching frequency range and the start-up signal is possible. As is also illustrated in FIG. 5, the inventive concepts described herein do not require absolute precision for effective operation of the inventive concepts, but rather adequate separation between the maximum normal switching frequency (f_{sw-max}) and the start-up frequency (fₛₜₐᵣₜ₋ᵤₚ) to differentiate between the two signals.

For example, FIG. 6 shows how the start-up signal can be used at start-up to co-ordinate an exact time that the Gate driver 400 activates the Gate driver's output despite not knowing exactly when a particular Gate driver is actually powered up. For example, the start-up signal can be used during start-up of the Gate driver to provide the power to start the Gate driver. When the Gate driver powers up, however, the Gate driver realizes that the Gate driver is being driven with the start-up signal. When the Gate driver is aware that the Gate driver has been powered up, and since the Gate driver is being driven with the start-up signal, the Gate driver is ready to start driving the Gate output signal as soon as the Gate driver is provided with an input signal that is in the normal switching frequency range.

Accordingly, at 802, the method 800 comprises determining when a common start-up signal having a first frequency and a second signal having a second frequency different from the first frequency is provided to multiple Gate drivers configured to coordinate a start-up of the multiple Gate drivers for driving output Gate signals to corresponding Gates. For example, a trinary input signal 602 is generated at a first frequency (e.g., a frequency above the f_{sw-max}) and input to the over-frequency detector 402 and to counter logic circuit 406. A gate driver supply voltage V₊ (e.g., V_{CC}) can be generated and supplied to the gate driver 400. For example, a Schottky diode 403 can be used to rectify the trinary input signal 602. The rectified signal forms a power supply voltage (V_{H}) which is then regulated by the on-chip voltage regulators to provide the V_{CC}, V_{GT}, and V_{1P5} power supply voltage rails. As noted above, after a gate driver exits UVLO (see 604), the gate driver needs to power up. Thus, when the counter logic circuit 406 detects the over frequency value (e.g., fₛₜₐᵣₜ₋ᵤₚ), which is a frequency above the >frequency 404 (e.g., f_{>detect}) for a predetermined count (n>C), the counter logic circuit 406 transmits the start-up signal to the gate drive logic circuit 401, which wakes up the gate drive logic circuit 401. Thereafter, when the gate drive logic circuit 401 receives the on signal (see 411 of FIG. 4) from trinary input logic 410 (e.g., see 606, normal switching frequency range, f_{sw-min} to f_{sw-max}), the gate drive logic circuit 401 provides a drive signal 608 to one of the gates in the gate drive output buffer 414.

FIG. 7 shows how the start-up signal can be used to achieve rapid shut-down of the universal gate driver 300. For example, when the gate drive logic circuit 401 receives the on signal from trinary input logic 410 (e.g., see 706, normal switching frequency range, f_{sw-min} to f_{sw-max}), the gate drive logic circuit 401 provides a drive signal 708 to one of the gates in the gate drive output buffer 414. When the over-frequency detector 402 and the counter logic circuit 406 detect a signal with a frequency above the f_{sw-max} (see 702) for a predetermined count (n>C), the counter logic circuit 406 transmits the shut-down signal (e.g., a common shut-down signal) to the gate drive logic circuit 401, which begins a rapid shut-down process (latching) of the Gate driver 400. Thereafter, when the gate drive logic circuit 401 receives the off signal from trinary input logic 410 (see 704), normal switching frequency range, f_{sw-min} to f_{sw-max}), and a shut-down signal from an under-frequency detector 416, the gate drive logic circuit 401 continues to stop providing a drive signal 708 to one of the gates in the gate drive output buffer 414. For example, the gate driver 400 logic is configured to have differentiated shut-down modes. For example, shut-down behavior is slightly different for a rapid shut-down and a fast shut-down. For example, in order for a system controller (e.g., the controller 106 and the controller 206) to communicate which shut-down method should be deployed, the gate driver 400 logic is differentiated according to whether the under-frequency detector 416 or the over-frequency detector 402 is activated. Accordingly, the detection of an over frequency results in the activation of the rapid shut-down scheme and the detection of an under frequency results in the activation of the fast shut-down.

While the foregoing is directed to embodiments of the present disclosure, other and further embodiments of the disclosure may be devised without departing from the basic scope thereof, and the scope thereof is defined by the claims that follow.

1. A switch of a bridge configured for use with a power converter, comprising:
multiple Gate drivers coupled to corresponding Gates and configured to coordinate a start-up of the multiple Gate drivers for driving output Gate signals to the corresponding Gates when a common start-up signal having a first frequency and a second signal having a second frequency different from the first frequency is provided to the multiple Gate drivers.

2. The bridge of claim 1, wherein the corresponding Gates are part of a Gallium-Nitride (GaN) High Electron Mobility Transistor comprising one of a Cascode GaN HEMT device, a gate injection transistor (GIT) GaN eHEMT device, or a Schottky Gate GaN eHEMT device.

3. The bridge of claim 1, wherein the first frequency is greater than the second frequency.

4. The bridge of claim 1, wherein the first frequency is provided to the multiple Gate drivers after reaching a predetermined count.

5. The bridge of claim 1, wherein the second signal is an on signal.

6. The bridge of claim 1, wherein the multiple Gate drivers are further configured to stop driving output Gate signals to the corresponding Gates when a common shut-down signal having the first frequency is provided to the multiple Gate drivers to perform rapid shut-down of the multiple Gate drivers.

7. A power conversion system, comprising:
a converter;
a DC component coupled to a DC side of the converter;
a plurality of switches coupled to a primary winding of a transformer; and
a bridge coupled to a secondary winding of the transformer and comprising a switch, the switch comprising:
multiple Gate drivers coupled to corresponding Gates and configured to coordinate a start-up of the multiple Gate drivers for driving output Gate signals to the corresponding Gates when a common start-up signal having a first frequency and a second signal having a second frequency different from the first frequency is provided to the multiple Gate drivers.

8. The power conversion system of claim 7, wherein the corresponding Gates are part of a Gallium-Nitride (GaN) High Electron Mobility Transistor comprising one of a Cascode GaN HEMT device, a gate injection transistor (GIT) GaN eHEMT device, or a Schottky Gate GaN eHEMT device.

9. The power conversion system of claim 7, wherein the first frequency is greater than the second frequency.

10. The power conversion system of claim 7, wherein the first frequency is provided to the multiple Gate drivers after reaching a predetermined count.

11. The power conversion system of claim 7, wherein the second signal is an on signal.

12. The power conversion system of claim 7, wherein the multiple Gate drivers are further configured to stop driving output Gate signals to the corresponding Gates when a common shut-down signal having the first frequency is provided to the multiple Gate drivers to perform rapid shut-down of the multiple Gate drivers.

13. A method for coordinating a start-up of multiple Gate drivers, comprising:
determining when a common start-up signal having a first frequency and a second signal having a second frequency different from the first frequency is provided to multiple Gate drivers configured to coordinate a start-up of the multiple Gate drivers for driving output Gate signals to corresponding Gates.

14. The method of claim 13, wherein the corresponding Gates are part of a Gallium-Nitride (GaN) High Electron Mobility Transistor comprising one of a Cascode GaN HEMT device, a gate injection transistor (GIT) GaN eHEMT device, or a Schottky Gate GaN eHEMT device.

15. The method of claim 13, wherein the first frequency is greater than the second frequency.

16. The method of claim 13, wherein the first frequency is provided to the multiple Gate drivers after reaching a predetermined count.

17. The method of claim 13, wherein the second signal is an on signal.

18. The method of claim to 17, wherein the multiple Gate drivers are further configured to stop driving output Gate signals to the corresponding Gates when a common shut-down signal having the first frequency is provided to the multiple Gate drivers to perform rapid shut-down of the multiple Gate drivers.
